(19) United States
(12) Patent Application Publication
(10) Pub. No.: US 2012/0015279 A1
(43) Pub. Date: Jan. 19, 2012

(54) DENSE THIN FILIM, FUEL CELL USING THE SAME AND FABRICATION METHODS THEREOF

(75) Inventors: Ji-Won SON, Seoul (KR); Hae-Weon LEE, Seoul (KR); Chang Woo KWON, Gyeonggi-Do (KR); Ki-Bum KIM, Seoul (KR); Jong Ho LEE, Seoul (KR)

(73) Assignee: KOREA INSTITUTE OF SCIENCE AND TECHNOLOGY, Seoul (KR)

(21) Appl. No.: 13/176,216

(22) Filed: Jul. 5, 2011

(30) Foreign Application Priority Data
Jul. 16, 2010 (KR) 10-2010-0069211

(51) Int. Cl. H01M 8/10; B05D 5/12; H01M 8/00; C23C 16/44; B32B 3/10; B05D 1/36

(52) U.S. Cl. 429/479; 428/138; 427/402; 216/95; 427/255.28; 427/58

(57) ABSTRACT

Disclosed is a dense thin film, a fuel cell using the same and fabrication methods thereof. A method for fabricating a dense thin film comprises (1) forming a first thin film on a porous surface, and (2) forming, on a surface of the first thin film, a second thin film made of a homogeneous material with respect to the first thin film, thereby removing pinholes of the first thin film. The method for fabricating a dense thin film may comprise (1′) forming a first thin film on a porous surface, (2′) forming, on a surface of the first thin film, a second thin film made of a to heterogeneous material with respect to the first thin film, thereby removing pinholes of the first thin film, and (3′) etching a surface of the second thin film. A dense thin film comprises a porous material, a first thin film formed on a surface of the porous material and having pinholes, a blocking material including a homogeneous or heterogeneous material with respect to the first thin film and configured to block the pinholes, and a second thin film including a homogeneous or heterogeneous material with respect to the first thin film and formed on a surface of the first thin film.

### CROSS-REFERENCE TO RELATED APPLICATION

This application claims the benefit of Korean Patent Application No. 10-2010-0069211, filed on Jul. 16, 2010, which is hereby incorporated by reference for all purposes as if fully set forth herein.

### BACKGROUND OF THE INVENTION

1. Field of the Invention

This specification relates to a dense thin film, a fuel cell using the same and fabrication methods thereof, and particularly, to a thin film capable of preventing gas leakage by blocking pinholes having a porous structure, a micro-fuel cell using the same and fabrication methods thereof.

2. Background of the Invention

As portable electronic devices have complicated and versatile functions, a high energy density is not satisfied by the conventional portable power. This may require new portable power. New power conditions include a high output density, a long operation time, a long lifespan, a low cost, and so on. In order to satisfy these conditions, fuel cells are being spotlighted.

Generally, the fuel cell consists of an electrolyte, a cathode and an anode. The fuel cells may be categorized according to an electrolyte material. Among the fuel cells, a fuel cell using a ceramic material (solid oxide) as an electrolyte is called a Solid Oxide Fuel Cell (SOFC). This SOFC has been developed for large power generation owing to its advantages such as high efficiency and capability of using various fuels rather than hydrogen. However, in correspondence to recent high demands for portable power of a high output and a high energy density, small portable power is being spotlighted.

The SOFC has to be operated at a low temperature and has to be microminiaturized so as to be developed as small portable power. The conventional large-scale SOFC is operated at a high temperature more than 800° C., which may cause performance degradation due to an interfacial reaction, thermal expansion mismatch of components such as an electrolyte, an electrode and a sealing material, etc.

However, when the operating temperature is low, conductivity of an electrolyte or activation of a catalyst is lowered to cause performance degradation of the fuel cell. Accordingly, a new material has to be adopted or a structure has to is be changed.

The conventional problem that an electrolyte has low conductivity due to the decrease of an operating temperature may be solved by reducing a resistance by making an electrolyte thickness thin. For this, a thin film process has been researched rather than the conventional bulk ceramic process. When fabricating a small fuel cell having a size of μm rather than the conventional centimeter (cm), meter (m) and millimeter (mm), the conventional powder process has a difficulty in being used. Accordingly, a small SOFC requires microminiaturization techniques such as a nano technology, a thin film process, micro-fabrication and MEMS (Micro Electro Mechanical Systems) technology. Accordingly, a small SOFC may be implemented by nano-micro technology for adjusting an operating temperature of a fuel cell and maintaining a high output and a high energy density even at a low temperature (e.g., enhanced electrode activation at a low temperature through a nano structure of an electrode and increased conductance of the electrolyte at a low temperature through a thin-film electrolyte), micro fabrication technology for integration and microminiaturization with consideration of matching among components of a fuel cell having undergone a thin film process and a nano structure process, and MEMS technology.

In a case where a small SOFC is implemented by using MEMS technology, when an electrolyte thin film is deposited on a dense substrate such as a silicon to substrate (Huang et al, J. Electrochemical Soc., 154(1) B20-24, Shim et al, Chemistry of Materials, 19, 3850-3854), the electrolyte thin film is densely formed to achieve an open circuit voltage (OCV) close to a theoretical value without gas leakage. Furthermore, a single cell has an enhanced performance at a low temperature. However, if a back etching and an electrode formation are not performed after forming the electrolyte on the dense surface, an open close voltage (OCV) is low and a single cell has a degraded configuration (Evans et al, J. Power Sources, 194, 119-129). That is, a performance of a single cell is severely influenced on a status of a surface on which an electrolyte thin film is formed and processing sequences for fabricating a single cell. Especially, an electrode of a fuel cell has to be formed to have a porous structure. However, a material and processes of the porous electrode are limited under the above processing procedures.

An OCV is not achieved when a thin film is formed on a general porous substrate rather than a dense substrate. The reasons is because a nucleus of a thin film is selectively generated on a porous surface to cause a difficulty in obtaining a pinholes-free dense thin film. These pinholes may be parts where a fuel and an oxidant are mixed to each other. This may lower an OCV, and cause performance degradation and destruction of a single cell due to partial overheating.

### SUMMARY OF THE INVENTION

Therefore, an aspect of the detailed description is to provide a dense thin film electrolyte capable of preventing a gas mixture by preventing pinholes formed on a porous surface, and to provide a micro-fuel cell capable of having an enhanced performance, reliability and stability.

Another aspect of the detailed description is to provide a method for fabricating a pinholes-free thin film and a method for fabricating a micro-fuel cell using the same.

Still another of the detailed description is to provide a method for fabricating a thin film capable of implementing various designs and patterns of a fuel cell and integration by being compatible with methods for fabricating various thin films including an electrolyte thin film, micro fabrication technology and MEMS technology, and capable of reducing integration and production costs with a small size of a fuel cell.

To achieve these and other advantages and in accordance with the purpose of this specification, as embodied and broadly described herein, there is provided a method for fabricating a dense thin film, comprising: (1) forming a first thin film on a porous surface; and (2) forming, on a surface of the first thin film, a second thin film made of a homogeneous material with respect to the first thin film, thereby removing pinholes of the first thin film. Alternatively, the method for fabricating a dense thin film may comprise (1′) forming a first thin film on a porous surface; (2′) forming, on a surface of the first thin film, a second thin film made of a heterogeneous material with respect to the first thin film, thereby removing pinholes of the first thin film; and (3′) etching a surface of the second thin film.

To achieve these and other advantages and in accordance with the purpose of this specification, as embodied and broadly described herein, there is also provided a method for fabricating a micro-fuel cell, comprising: (1) forming a first electrode on a porous surface; (2) forming a first electrolyte thin film, either on the first electrode, or on a part on the porous surface where the first electrode is not formed and on a surface of the first electrode; (3) forming, on a surface of the first electrolyte thin film, a second thin film made of a homogeneous material with respect to the first electrolyte thin film, thereby removing pinholes of the first electrolyte thin film; and (4) forming a second electrode on a surface of the second thin film. Alternatively, the method for fabricating a micro-fuel cell may comprise: (1′) forming a first electrode on a porous surface; (2′) forming a first electrolyte thin film, either on the first electrode, or on a part on the porous surface where the first electrode is not formed and on a surface of the first electrode; (3′) forming, on a surface of the first electrolyte thin film, a second thin film made of a heterogeneous material with respect to the first electrolyte thin film, hereby removing pinholes of the first electrolyte thin film; (4′) etching a surface of the second thin film; and (5′) forming a second electrode on the surface of the second thin film having undergone the step of (4′).

To achieve these and other advantages and in accordance with the purpose of this specification, as embodied and broadly described herein, there is still also provided a dense thin film, comprising: a porous material; a first thin film formed on a surface of the porous material, and having pinholes; and a second thin film including a homogeneous material with respect to the first thin film, formed on a surface of the first thin film, and configured to block the pinholes. Alternatively, the dense thin film of the present invention may comprise a porous material; a first thin film formed on a surface of the porous material, and having pinholes; a blocking material including a heterogeneous material with respect to the first thin film, and configured to block the pinholes; and a second thin film including a homogeneous material with respect to the first thin film, and formed on a surface of the first thin film.

To achieve these and other advantages and in accordance with the purpose of this specification, as embodied and broadly described herein, there is yet still also provided a micro-fuel cell, comprising: a porous material; a first electrode formed on a surface of the porous material; an electrolyte thin film having pinholes, and formed either on the first electrode, or on a part of the porous surface where the first electrode is not formed and a surface of the first electrode; a second thin film including a homogeneous material with respect to the electrolyte thin film, formed on a surface of the electrolyte thin film, and configured to block the pinholes; and a second electrode formed on a surface of the second thin film. Alternatively, the micro-fuel cell may comprise a porous material; a first electrode formed on a surface of the porous material; a first electrolyte thin film having pinholes, and formed either on the first electrode, or on a part on the porous surface where the first electrode is not formed and on a surface of the first electrode; a blocking material including a heterogeneous material with respect to the first electrolyte thin film, and configured to block the pinholes; a second electrolyte including a homogeneous material with respect to the first electrolyte thin film, and formed on a surface of the first electrolyte thin film; and a second electrode formed on a surface of the second electrolyte.

The present invention may have the following advantages.

Firstly, may be obtained a dense thin film electrolyte structure capable of preventing a gas mixture regardless of a state of a surface on which an electrolyte thin film is deposited. This may implement a thin film electrolyte micro-fuel cell having an enhanced performance and high reliability.

Secondly, the method for fabricating a dense thin film according to the present invention may be achieved by using a thin film process capable of implementing high density integration and massive production. This may allow excellent portability, extensibility and generality (compatibility) to other fields rather than an electrolyte for a fuel cell. Accordingly, this method may have an extensity to each kind of thin film membrane device which requires a dense thin film on a porous surface, e.g., a sensor, a hydrogen generator cell, etc.

Thirdly, the micro-fuel cell fabricated according to the present invention serving as a small mobile power supply device for the next generation may allow high integration and microminiaturization of a fuel cell. This may be advantageous in an economical aspect.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the detailed description.

### BRIEF DESCRIPTION OF THE DRAWINGS

The accompanying drawings, which are included to provide a further understanding of the invention and are incorporated in and constitute a part of this specification, illustrate exemplary embodiments and together with the description serve to explain the principles of the invention.

In the drawings:

FIG. 1 is a view illustrating a method for fabricating a dense thin film according to the present invention;

FIG. 2 is a sectional view of a dense thin film according to the present invention;

FIG. 3 is a sectional view of a dense thin film according to the present invention;

FIG. 4 is a sectional view of a micro-fuel cell having a thin film type electrode formed on a porous supporter according to the present invention;

FIG. 5 is a transmission electron microscopy (TEM) image of a YSZ electrolyte deposited on a porous surface;

FIGS. 6A and 6B are graphs illustrating open circuit voltages (OCVs) of a micro-fuel cell of a first example according to the lapse of time, in which

FIG. 6A illustrates a case where pinholes of a 300 nm YSZ electrolyte are not blocked, and

FIG. 6B illustrates a case where the pinholes of the 300 nm YSZ electrolyte are blocked by an atomic layer deposition (ALD);

FIGS. 7A, 7B, 7C and 7D are graphs illustrating open circuit voltages (OCVs) of a micro-fuel cell of the present invention according to the lapse of time, in which

FIG. 7A illustrates a case where pinholes of a 600 nm YSZ electrolyte are not blocked,

FIG. 7B illustrates a case where the pinholes of the 600 nm YSZ electrolyte are blocked by atomic layer deposition (ALD),

FIG. 7C illustrates a case where pinholes of a 900 nm YSZ electrolyte are not blocked, and

FIG. 7D illustrates a case where the pinholes of the 900 nm YSZ electrolyte are blocked by atomic layer deposition (ALD); and

FIG. 8 is a graph illustrating an output characteristic of a 900 nm YSZ electrolyte according to the present invention.

### DETAILED DESCRIPTION OF THE INVENTION

Description will now be given in detail of the exemplary embodiments, with reference to the accompanying drawings. For the sake of brief description with reference to the drawings, the same or equivalent components will be provided with the same reference numbers, and description thereof will not be repeated.

A method for fabricating a dense thin film according to the present invention may comprise (1) forming a first thin film on a porous surface, and (2) forming, on a surface of the first thin film, a second thin film made of a homogeneous material with respect to the first thin film, thereby removing pinholes of the first thin film. Alternatively, the method for fabricating a dense thin film may comprise (1′) forming a first thin film on a porous surface, (2′) forming, on a surface of the first thin film, a second thin film made of a heterogeneous material with respect to the first thin film, thereby removing pinholes of the first thin film, and (3′) etching a surface of the second thin film.

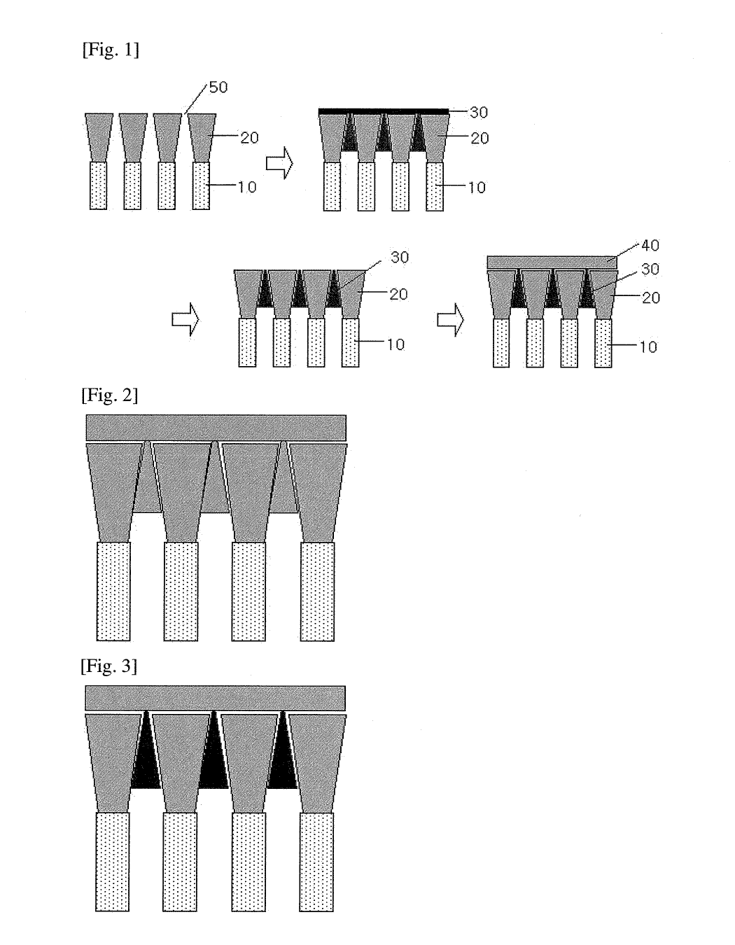

FIG. 1 is a view illustrating a method for fabricating a dense thin film according to the present invention.

As shown in FIG. 1A, once a first thin film 20 is formed on a porous surface 10, pinholes 50 are formed in the first thin film due to pores of the surface (step (1) or (1′)). In order to solve these pinholes, a second thin film 30 is formed as shown in FIG. 1B. The second thin film serves to block the pinholes, and is formed on the surface of the first thin film (step (2) or (2′)).

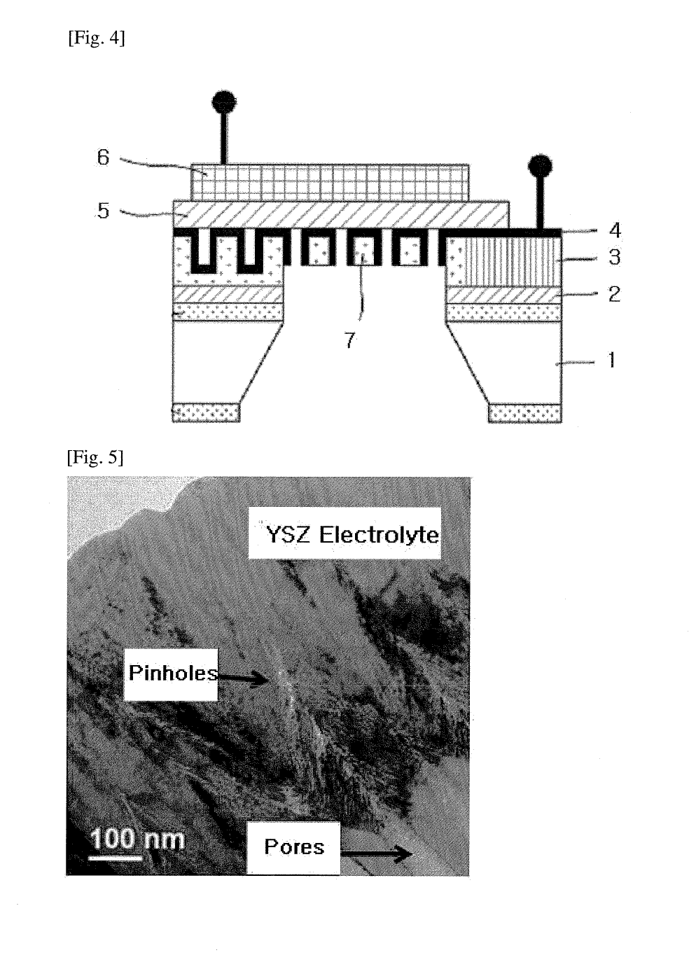

In a case where the second thin film is formed of a homogeneous material with respect to the first thin film, a dense thin film of FIG. 2 is completely fabricated merely through the above steps.

In a case where the second thin film is formed of a heterogeneous material with respect to the first thin film, an additional process is required. After blocking the pinholes as shown in FIG. 10, the second thin film formed on the surface of the first thin film is etched to be removed (step (3′). The etching is performed until the second thin film material blocks the pinholes and the first thin film is exposed.

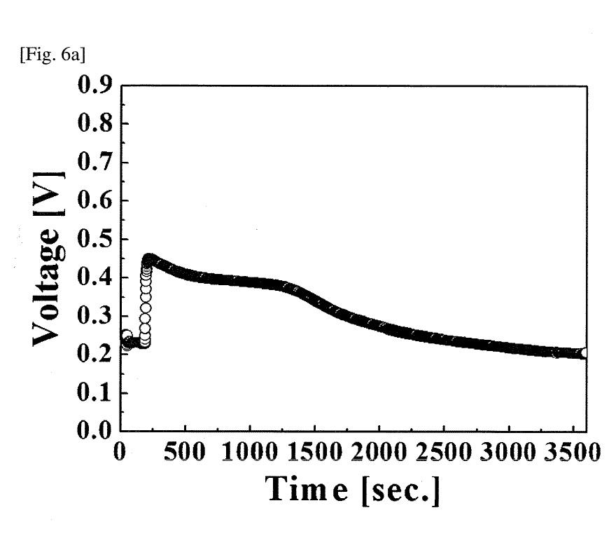

The method may further comprise depositing a homogeneous or heterogeneous material with respect to the first thin film on the surface of the second thin film having undergone the step (3′). The fabricated dense thin film may have a structure in which a third thin film 40 has been formed as shown in FIG. 3.

The second thin film may be formed by an atomic layer deposition (ALD), or a chemical vapor deposition (CVD), or a chemical solution deposition.

A method for fabricating a micro-fuel cell may comprise (1) forming a first electrode on a porous surface, (2) forming a first electrolyte thin film, either on the first electrode, or on a part on the porous surface where the first electrode is not formed and on a surface of the first electrode, (3) forming, on a surface of the first electrolyte thin film, a second thin film made of a homogeneous material with respect to the first electrolyte thin film, on thereby removing pinholes of the first electrolyte thin film, and (4) forming a second electrode on a surface of the second thin film. Alternatively, the method for fabricating a micro-fuel cell may comprise (1′) forming a first electrode on a porous surface, (2′) forming a first electrolyte thin film, either on the first electrode, or on a part on the porous surface where the first electrode is not formed and on a surface of the first electrode, (3′) forming, on a surface of the first electrolyte thin film, a second thin film made of a heterogeneous material with respect to the first electrolyte thin film, thereby removing pinholes of the first electrolyte thin film, (4′) etching a surface of the second thin film, and (5′) is forming a second electrode on the surface of the second thin film having undergone the step of (4′) and the exposed first electrolyte thin film. The etching may be performed to remove the second thin film and to expose the first thin film. And, the etching is a process for removing insulating materials which exist on the surface of an electrolyte so as to contact the electrolyte to an electrode when the second thin film is formed of insulating materials.

In step (5′), for an enhanced quality of the electrolyte, a second electrolyte thin film made of a homogeneous or heterogeneous material with respect to the first electrolyte may be formed on the surface of the second thin film having undergone the step (4′), and then a second electrode may be formed on the surface of the second electrolyte thin film.

The pinholes may be blocked with using a homogeneous or heterogeneous electrolyte material with respect to the first electrolyte, or a heterogeneous insulating material. The insulating material may be selected from a group consisting of a silicon oxide (SiOₓ), a silicon nitride (SiₓN_{y}), an aluminum oxide (AlₓO_{y}), a magnesium oxide (MgₓO_{y}), a titanium oxide (TiₓO_{y}), etc. However, the present invention is not limited to this.

The second thin film may be formed by an atomic layer deposition (ALD), or a chemical vapor deposition (CVD), or a chemical solution deposition.

The dense thin film according to the present invention may comprise a porous material, a first thin film formed on a surface of the porous material and having pinholes, a blocking material including a homogeneous or heterogeneous material with respect to the first thin film and configured to block the pinholes, and a second thin film including a homogeneous or heterogeneous material with respect to the first thin film and formed on a surface of the first thin film. The blocking material configured to block the pinholes may be a homogeneous material with respect to the first thin film (refer to FIG. 2), or a heterogeneous material with respect to the first thin film (refer to FIG. 3).

A micro-fuel cell according to the present invention may comprise a porous material, a first electrode formed on a surface of the porous material, an electrolyte thin film having pinholes and formed either on the first electrode, or on a part on the porous surface where the first electrode is not formed and on a surface of the first electrode, a blocking material including a homogeneous or heterogeneous material with respect to the first electrolyte thin film and configured to block the pinholes, a second electrolyte thin film including a homogeneous or heterogeneous material with respect to the first electrolyte thin film and formed on a surface of the electrolyte thin film, and a second electrode formed on a surface of the second electrolyte thin film.

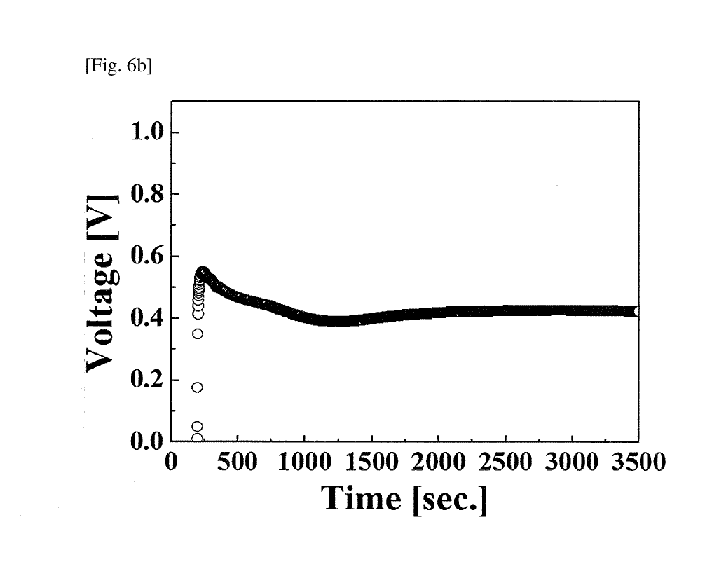

FIG. 4 is a sectional view of a micro-fuel cell having a thin film type electrode formed on a porous supporter according to the present invention.

As shown in FIG. 4, the micro-fuel cell may have a structure in which an electrolyte 5 is disposed between a first electrode 4 and a second electrode 6, or may have a structure in which a first electrode 4 and a second electrode 6 are disposed on one surface of an electrolyte 5 with a non-contacted state.

The first electrode 4 serving as an anode (fuel or oxidation electrode) may be formed of a material selected from a group consisting of nickel (Ni), ruthenium (Ru), palladium (Pd), rhodium (Rd), platinum (Pt) and an alloy thereof, a cermet composite between the metallic material and YSZ, GDC, etc., a ruthenium oxide, etc.

The second electrode 6 serving as a cathode (air or reduction electrode) may be formed of a material selected from a group consisting of noble metals such as platinum (Pt), gold (Au), silver (Ag), or lanthanum oxide-based perovskite such as lanthanum-strontium manganese oxide (LSM), lanthanum-strontium cobalt oxide (LSC), lanthanum-strontium iron oxide (LSF), lanthanum-strontium cobalt iron oxide (LSCF) and samarium-strontium cobalt oxide (SSC), a bismuth-ruthenium oxide based electrode, etc.

The first electrode 4 may be a cathode, and the second electrode 6 may be an anode.

The electrolyte may be formed of a material selected from a group consisting of zirconium oxide (ZrₓO_{y}), cerium oxide (CeₓO_{y}), lanthanum gallate, barium cerate, barium zirconate, bismuth-based oxide or oxygen ion conducting materials doped with the above materials, or an ion conductor such as proton conducting materials.

The substrate 1 may be formed of a material selected from a group consisting of electronic conducting materials, electronic non-conducting materials, semi-conducting materials, oxygen ion conducting materials, proton conducting materials, etc. For instance, the substrate may be formed of a material selected from a group consisting of silicon (Si), silicon oxide (SiOₓ), silicon nitride (SiₓN_{y}), aluminum oxide (AlₓO_{y}), magnesium oxide (MgₓO_{y}), titanium oxide (TiₓO_{y}), zirconium oxide (ZrₓO_{y}), cerium oxide (CeₓO_{y}), lanthanum gallate, barium cerate, to barium zirconate, bismuth-based oxide and a material doped with the above materials.

In a case where semiconducting materials such as silicon (Si) wafer or electronic conducting materials are used as the substrate 1, a buffer layer for insulation and thermal expansion may be further formed on the substrate 1. The is buffer layer for thermal expansion indicates a buffer layer for reducing a stress due to thermal expansion. For instance, the buffer layer may be formed of a material selected from a group consisting of silicon oxide (SiOₓ), silicon nitride (SiₓN_{y}), aluminum oxide (AlₓO_{y}), magnesium oxide (MgₓO_{y}), titanium oxide (TiₓO_{y}), zirconium oxide (ZrₓO_{y}), cerium oxide (CeₓO_{y}), lanthanum gallate, barium cerate, barium zirconate, bismuth-based oxide and a material doped with the above materials.

In the micro solid oxide fuel cell of FIG. 4, an electrolyte is formed on a porous substrate so as to obtain a porous structure of the first electrode 4. The electrode of the fuel cell has to have a porous structure since a fuel and an oxidant have to reach up to an interface between an electrode and an electrolyte in a gaseous phase. A thin film electrolyte is deposited on the porous substrate by a thin film deposition method capable of maintaining pores and depositing an electrolyte with an orientation, such as sputtering, evaporation and pulsed laser deposition (PLD). A chemical vapor deposition (CVD)-based method cannot be used to form an electrolyte to maintain the porous nature of the electrode since a thin film is deposited even on a wall surface of a porous structure in a conformal manner to block pores.

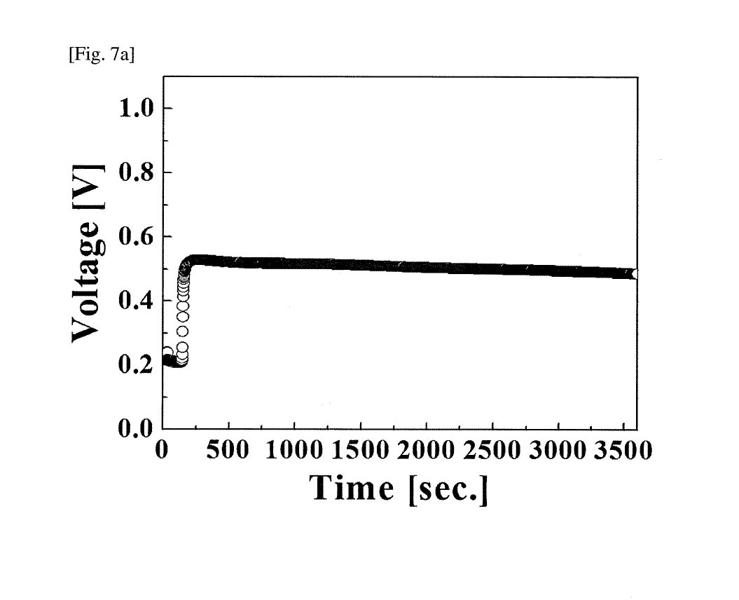

In a case where a thin film electrolyte is deposited on a porous structure, a nucleation position on the thin film is limited to a part rather than pores. This may cause pinholes to be generated on the thin film electrolyte. FIG. 5 is a transmission electron microscopy (TEM) image of a YSZ electrolyte deposited on a porous template. As can be seen from FIG. 5, an electrolyte thin film formed on pores has pinholes with a thick thickness. These pinholes may be parts where a fuel and an oxidant are mixed to each other under an operation condition of a solid oxide fuel cell (SOFC). This may reduce an open circuit voltage (OCV) due to an reduction of the gradient of the oxygen partial pressure at two ends of the electrolyte, resulting in performance degradation of a single cell. Furthermore, these pinholes may be parts where a fuel and oxygen are mixed to each other to generate direct combustion. This may cause degradation of the electrolyte thin film due to partial overheating.

These pinholes may be prevented to some degrees by increasing a thickness of the electrolyte thin film. However, the increment of the thickness of the electrolyte thin film may increase an ohmic resistance of a single cell. This may result in performance degradation of the single cell, and may cause the solid oxide fuel cell (SOFC) not to be successfully operated at a low temperature.

In the present invention, these pinholes are removed by a thin film deposition method for allowing a precursor to permeate the pinholes. As the pinholes are removed, a gas mixture may be prevented to enhance a performance and reliability of a single cell. The pinholes may be blocked by an atomic layer deposition (ALD), or a chemical vapor deposition (CVD), or a chemical solution deposition.

In the following examples, a micro-fuel cell according to the present invention was fabricated and a performance thereof was tested. However, the present invention is not limited to the following examples.

### Example 1

Low stress silicon nitride was deposited on a 300 μm thick Si wafer with a thickness of 500 nm by an LPCVD method. Then, one surface of the wafer having the silicon nitride deposited thereon was patterned. Here, the wafer was photosensitized by spin-coating a positive photo resist (AZ 1512) with using a is photomask having a square array of 520 μm×520 μm. After developing the photosensitized wafer with using a developing solution (developer), the silicon nitride was dry-etched with using the remaining photoresist as a mask. Then, the remaining photoresist was removed with using a photoresist removing solution.

Then, the silicon nitride was wet-etched by an etching solution at 80° C. for five hours. As the etching solution, used was a mixture of KOH, IPA and DIW (250 g:200 g:800 g). Then, the wafer was cut into a size of 2 cm×2 cm with using a dicing saw, and the cut wafer was washed with using an SPM (Sulfuric acid Peroxide Mixture) solution, etc.

Then, a TiN film (20 nm) and an Al film (1 μm) were deposited on the silicon nitride via DC-sputtering. Here, the TiN film was deposited via reactive sputtering under conditions of 5.3 mTorr, 150 W and 45 seconds in an Ar and N₂ atmosphere, and the Al film was deposited under conditions of 5 mTorr, 150 W and 16 minutes in an Ar atmosphere.

Then, the Al film underwent an anodizing process. The anodizing process was performed under conditions of 40 V, 10° C., 0.3 M oxalic acid (electrolyte). The Al film was removed by approximately 500 nm through a primary anodizing process. Then, the AAO having undergone the primary anodizing process was removed by being immersed in a mixture solution between 6 wt % phosphoric acid and 1.8 wt % chromic acid at 50° C. for 30 minutes. Then, the remaining Al film was completely removed through a secondary anodizing process for 500 seconds, thereby being transformed into alumina. Then, the alumina (Al₂O₃) thin film was etched at 30° C. for 10 minutes with using a mixture solution between 6 wt % phosphoric acid and 1.8 wt % chromic acid, thereby widening a pore size to 30˜40 nm from 20˜30 nm (pore widening).

Then, Pt (first electrode) was deposited with a thickness of 50 nm via DC-sputtering, and a YSZ electrolyte was deposited with a thickness of 300 nm at 300° C. by using pulse laser deposition (PLD).

Then, the alumina (Al₂O₃) thin film was deposited on the YSZ and on the surface of the pinholes with a thickness of 20 nm a temperature of 200° C. by atomic layer deposition (ALD) with using a precursor (Trimethyl aluminum) and a reactant (H₂O). Then, the alumina disposed on the YSZ was removed by a dry-etching process. Then, porous Pt (second electrode) was deposited with a thickness of approximately 100 nm via DC-sputtering. Here, the deposition was performed under conditions of 75 mTorr, 25 W and 200 seconds in an Ar atmosphere.

Finally, the barrier layers of silicon nitride, TiN and a barrier layer of AAO were sequentially dry-etched on a rear surface of the substrate, thereby obtaining a gas flow channel.

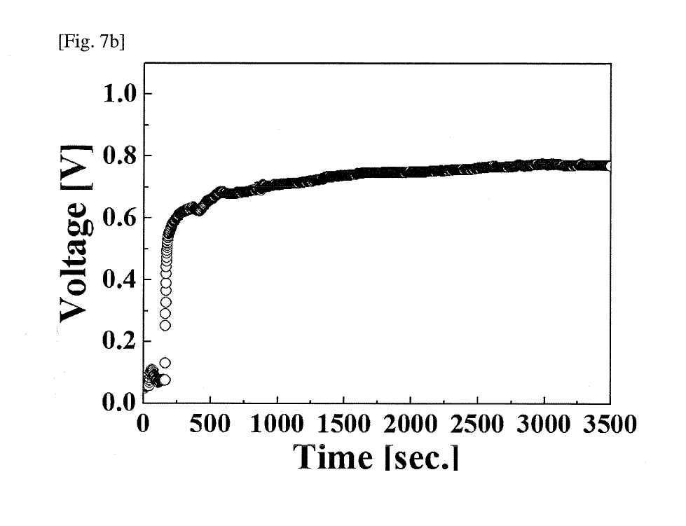

FIGS. 6A and 6B are graphs illustrating open circuit voltages (OCVs) of the micro-fuel cell according to the lapse of time when using atomic layer deposition (ALD). More concretely, FIG. 6A illustrates a change of an open circuit voltage (OCV) of a single cell with a 300 nm-thick YSZ electrolyte according to the lapse of time when pinholes are not blocked by atomic layer deposition (ALD), and FIG. 6B illustrates a change of an open circuit voltage (OCV) of a single cell with a 300 nm-thick YSZ electrolyte according to the lapse of time when pinholes are blocked by atomic layer deposition (ALD). As can be seen from FIGS. 6A and 6B, a high and stable OCV was achieved by blocking the pin holes.

### Example 2

Unlike the above Example 1, the YSZ electrolyte was fabricated to have a total thickness of 600 nm and 900 nm, respectively. A primary YSZ deposition was performed with a thickness of 300 nm and 450 nm, respectively. Next, Al₂O₃ was formed by ALD, and then was etched. Next, a 300 nm YSZ film and a 450 nm YSZ film were deposited, respectively.

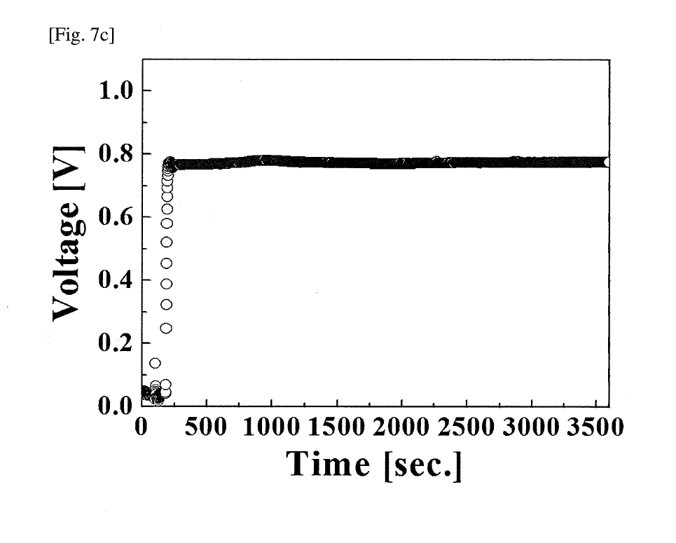

FIGS. 7A, 7B, 7C and 7D are graphs illustrating a change of an open circuit voltage (OCV) of a micro-fuel cell according to the lapse of time. More concretely, FIG. 7A illustrates a case where pinholes of a single cell with a 600 nm-thick YSZ electrolyte are not blocked by ALD, whereas FIG. 7B illustrates a case where pinholes of a single cell with a 600 nm-thick YSZ electrolyte are blocked by ALD. FIG. 7C illustrates a case where pinholes of a single cell with a 900 nm-thick YSZ electrolyte are not blocked by ALD, whereas FIG. 7D illustrates a case where pinholes of a single cell with a 900 nm-thick YSZ electrolyte are blocked by ALD. As can be seen from FIGS. 7A, 7B, 7C and 7D, a high and stable OCV was achieved by blocking the pin holes.

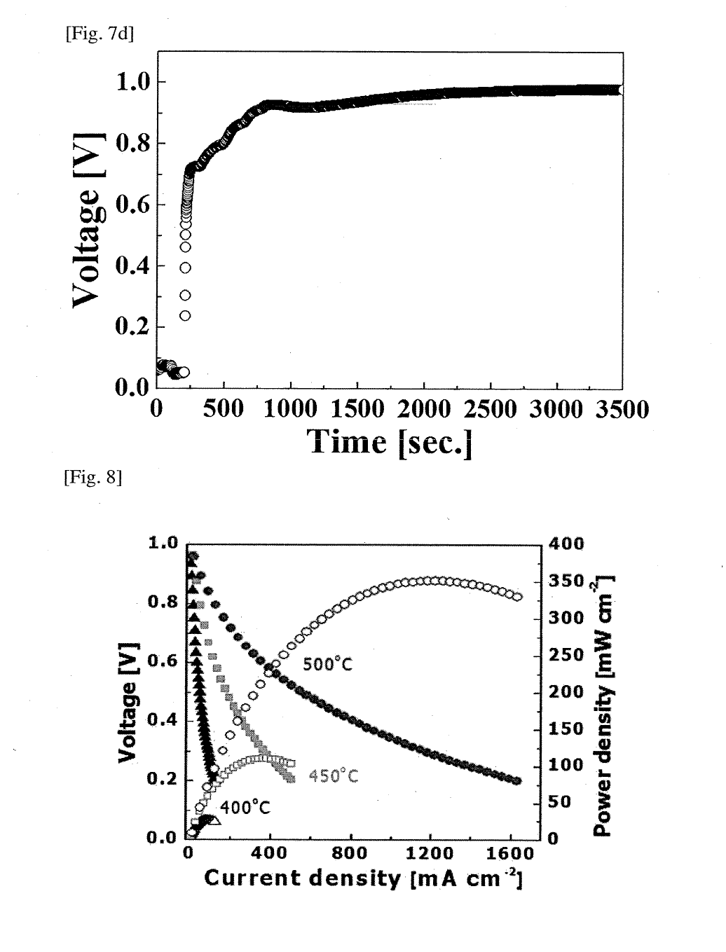

FIG. 8 is a graph illustrating an output characteristic of a single cell with a 900 nm-thick YSZ electrolyte according to a second example of the present invention.

Referring to FIG. 8, the single cell with a 900 nm-thick YSZ electrolyte exhibited an enhanced output density at a low temperature less than 500° C.

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A method for fabricating a dense thin film, comprising:
(1) forming a first thin film on a porous surface; and
(2) forming, on a surface of the first thin film, a second thin film made of a homogeneous material with respect to the first thin film, thereby removing pinholes of the first thin film.

2. A method for fabricating a dense thin film, comprising:
(1′) forming a first thin film on a porous surface;
(2′) forming, on a surface of the first thin film, a second thin film made of a heterogeneous material with respect to the first thin film, thereby removing pinholes of the first thin film; and
(3′) etching a surface of the second thin film.

3. The method of claim 2, wherein the etching is performed to remove the second thin film and to expose the first thin film.

4. The method of claim 2, further comprising depositing, on the surface of the second thin film having undergone the step of (3′), a homogeneous or heterogeneous material with respect to the first thin film.

5. The method of claim 1 or 2, wherein the second thin film is formed by an atomic layer deposition (ALD), or a chemical vapor deposition (CVD), or a chemical solution deposition.

6. A method for fabricating a micro-fuel cell, comprising:
(1) forming a first electrode on a porous surface;
(2) forming a first electrolyte thin film, either on the first electrode, or on a part on the porous surface where the first electrode is not formed and on a surface of the first electrode;
(3) forming, on a surface of the first electrolyte thin film, a second thin film made of a homogeneous material with respect to the first electrolyte thin film, thereby removing pinholes of the first electrolyte thin film; and
(4) forming a second electrode on a surface of the second thin film.

7. A method for fabricating a micro-fuel cell, comprising:
(1′) forming a first electrode on a porous surface;
(2′) forming a first electrolyte thin film, either on the first electrode, or on a part on the porous surface where the first electrode is not formed and on a surface of the first electrode;
(3′) forming, on a surface of the first electrolyte thin film, a second thin film made of a heterogeneous material with respect to the first electrolyte thin film, thereby removing pinholes of the first electrolyte thin film;
(4′) etching a surface of the second thin film; and
(5′) forming a second electrode on the surface of the second thin film having undergone the step of (4′).

8. The method of claim 7, wherein in the step of (5′), a second electrolyte thin film made of a homogeneous or heterogeneous material with respect to the first electrolyte thin film is formed on the surface of the second thin film having undergone the step of (4′), and then a second electrode is formed on a surface of the second electrolyte thin film.

9. The method of claim 7, wherein the etching is performed to remove the second thin film and to expose the first electrolyte thin film.

10. The method of claim 6 or 7, wherein the second thin film is formed by an atomic layer deposition (ALD), or a chemical vapor deposition (CVD), or a chemical solution deposition.

11. A dense thin film, comprising:
a porous material;
a first thin film formed on a surface of the porous material, and having pinholes;
a blocking material including a homogeneous or heterogeneous material with respect to the first thin film, and configured to block the pinholes; and
a second thin film including a homogeneous or heterogeneous material with respect to the first thin film, and formed on a surface of the first thin film.

12. A micro-fuel cell, comprising:
a porous material;
a first electrode formed on a surface of the porous material;
an electrolyte thin film having pinholes, and formed either on the first electrode, or on a part of the porous surface where the first electrode is not formed and a surface of the first electrode;
a blocking material including a homogeneous or heterogeneous material with respect to the electrolyte thin film, and configured to block the pinholes;
a second electrolyte thin film including a homogeneous or heterogeneous material with respect to the electrolyte thin film, and formed on a surface of the electrolyte thin film; and
a second electrode formed on a surface of the second electrolyte thin film.
